(19) United States
(12) Patent Application Publication
(10) Pub. No.: US 2026/0206150 A1
(43) Pub. Date: Jul. 16, 2026

(54) INVERTER MODULE

(71) Applicant: LG INNOTEK CO., LTD., Seoul (KR)

(72) Inventor: Ji Hwan JEON, Seoul (KR)

(73) Assignee: LG INNOTEK CO., LTD., Seoul (KR)

(21) Appl. No.: 19/136,762

(22) PCT Filed: Dec. 6, 2023
(86) PCT No.: PCT/KR2023/020041

§ 371 Date: Jun. 6, 2025

(30) Foreign Application Priority Data
Dec. 6, 2022 (KR) 10-2022-0169212

(51) Int. Cl. H05K 5/00; H05K 7/14

(52) U.S. Cl. CPC H05K 5/0069; H05K 7/1432

(57) ABSTRACT

A wire connection module, according to one embodiment of the present invention, for connecting an inverter drive part of an inverter module and external input/output lines, comprises: a wire connection part for connecting the inverter drive part and the external input/output lines; and a case in which the wire connection part is disposed, wherein the wire connection part comprises a plurality of substrates that are stacked, and the case has two through-holes formed on one side thereof, through which wires pass.

### TECHNICAL FIELD

The present invention relates to an inverter module, and more particularly, to an inverter module having efficient space utilization and a wire connection module connected thereto.

### BACKGROUND ART

Photovoltaic generation is becoming widely used as eco-friendly energy generation methods and replaces existing chemical power generation and nuclear power generation. Photovoltaic generation may be provided in a standalone type, in which a battery is connected to a converter, and a power grid-linked type. In general, the standalone type power generation is constituted by solar cells, storage batteries, and power conversion devices, and the power grid-linked system is connected to a commercial power source so that power is exchanged with a load grid line.

Electricity generated by photovoltaic panels is not used directly in homes or buildings and thus is converted into usable electricity using a power conversion device such as an inverter. However, when the inverter performs the power conversion, a lot of heat is generated, and the heat deteriorates performance, and thus, heat dissipation is important. In addition, since the inverter is installed in external environments, sealing is important to prevent foreign substances from being introduced into the inverter, and development of technology for efficiently placing elements into an inverter module is necessary.

### DISCLOSURE OF THE INVENTION

### Technical Problem

The technical problem to be solved by the present invention is to provide an inverter module having efficient space utilization and a wire connection module connected thereto.

### Technical Solution

To solve the above technical problem, a wire connection module configured to an inverter driving unit of an inverter module to external input/output lines according to an embodiment of the present invention includes: a wire connection unit configured to connect the inverter driving unit to the external input/output lines; and a case in which the wire connection unit is disposed, wherein the wire connection unit includes a plurality of substrates that are stacked, and the case has two through-holes, through which a wire passes, in one side surface thereof.

In addition, the wire connection unit may have a structure in which an upper layer and a lower layer are stacked, wherein the lower layer may include: a first substrate disposed at a center and having one side connected to an external power input line; a switching part disposed at a side in a first direction; a second substrate disposed at a side in the first direction and having one side connected to an output part of the switching part and the other side connected to the power input part of the inverter driving unit through one through-hole of the two through-holes; and a third substrate disposed at a side in a second direction and having one side connected to a power output part of the inverter driving unit through the other through-hole of the two through-holes and the other side connected to the external power output line.

In addition, DC power may be input/output into/from the first substrate and the second substrate, and AC power may be input/output into/from the third substrate.

In addition, the upper layer may include: a fourth substrate disposed at a side in the first direction and having one side connected to the first substrate and the other side connected to the switching part; a fifth substrate disposed at a center and connected to a communication part of the inverter driving unit; and a sixth substrate disposed at a side in the second direction and connected to the communication part of the inverter driving unit.

In addition, the first substrate may at least partially overlap in the direction of stacking, and the first substrate may include a connector connected to the external power input line, wherein the connector is disposed on a first area of the first substrate including at least a portion of an area that overlaps the first substrate in the direction of stacking, and a coupling surface coupled to the external power input line protrudes to be inclined toward an internal space region in which the fifth substrate is not disposed.

In addition, the first to fourth substrates may be connected to a power system line, and the fifth and sixth substrates may be connected to a communication system line.

In addition, each of the first to sixth substrates may include a programmable logic controller (PLC) part, an arc fault circuit interrupter (AFCI) part, an AC power output part, an electromagnetic interference (EMI) filter part, an energy management system (EMS) part, and a communication part.

In addition, the case may include two air inlet-outlets, which respectively face the two through-holes, on a side surface facing the one side surface in which the two through-holes are defined.

In addition, one of the two air inlet-outlets may be configured to allow air to be introduced from the outside, and the other may be configured to allow air to be discharged to the outside.

In addition, the case may include a plurality of coupling hole forming guides, which are configured to define coupling holes having multiple diameters, on a side surface facing the one side surface in which the two through-holes are defined, wherein the coupling holes may be defined to be through-coupled when connected to the external input/output lines.

In addition, the case may include a stepped portion on which a switch knob of the switching part is disposed on an outer surface of the side surface in the first direction, the switch knob may include a locking bar that is inserted and fixed into the inside of the switch knob when the switch knob is in an off position, and the stepped portion may be provided to be opened in a direction in which the locking bar is directed when the switch knob rotates.

In addition, the locking bar may be disposed to protrude downward from the second case more than a bottom surface of the second case when the switch knob is in an on position.

### Advantageous Effects

According to the embodiments of the present invention, the space utilization efficiency may be improved. In addition, it may be easy to be assembled, and the heat dissipation performance may be improved through the air circulation. The easy of the coupling between the cases may increase. In addition, the coupling may be performed through the coupling points that are evenly distributed at the inside and outside, the reduction in material costs and the simplification of the manufacturing process may be enabled, and the screw coupled to the inside of the wire connection unit may be minimized to improve the workability.

Furthermore, the space for the wire connection may be efficiently utilized, the wire may be prevented from being twisted or tangled, and the one holder may simultaneously press and couple the plurality of switching elements to the heatsink and the substrate.

### BRIEF DESCRIPTION OF THE DRAWINGS

FIG. 1 is a perspective view of an inverter module according to an embodiment of the present invention.

FIG. 2 is a view illustrating the inside of the inverter module according to an embodiment of the present invention.

FIG. 3 is a view illustrating an inverter module case according to an embodiment of the present invention.

FIG. 4 is a view for explaining a wire connection module case according to an embodiment of the present invention.

FIGS. 5 to 8 are views for explaining a wire connection module case cover according to an embodiment of the present invention.

FIGS. 9 to 12 are views for explaining a configuration of a wire connection unit according to an embodiment of the present invention.

FIGS. 13 and 14 are views for explaining an air circulation of an inductor module according to an embodiment of the present invention.

FIG. 15 is a view for explaining a hole guide of the inductor module according to an embodiment of the present invention.

FIGS. 16 and 17 are views for explaining a switch knob of the inductor module according to an embodiment of the present invention.

FIGS. 18 to 20 are views for explaining an inductor module case according to an embodiment of the present invention.

FIG. 21 is a view for explaining a configuration of an inductor drive part according to an embodiment of the present invention.

FIGS. 22 to 25 are views for explaining a switching element module according to an embodiment of the present invention.

FIGS. 26 and 27 are views for explaining a busbar of the inductor module according to an embodiment of the present invention.

FIGS. 28 and 29 are views for explaining a circular busbar of the inductor module according to an embodiment of the present invention.

FIG. 30 is a view for explaining a structure of an embedded inductor of the inductor module according to an embodiment of the present invention.

### MODE FOR CARRYING OUT THE INVENTION

Hereinafter, preferred embodiments of the present invention will be described in detail with reference to the accompanying drawings.

However, the technical idea of the present invention is not limited to some of the embodiments described, but may be implemented in various different forms, and one or more of the components in embodiments may be selectively combined or substituted for use even within the scope of the technical idea of the present invention.

In addition, terms (including technical and scientific terms) used in the embodiments of the present invention may be interpreted as having a meaning that may be generally understood by a person of ordinary skill in the technical field to which the present invention belongs, unless explicitly and specifically defined and described, and the terms that are commonly used, such as terms defined in a dictionary, may be interpreted in consideration of the contextual meaning of the relevant technology.

In addition, the terms used in the embodiments of the present invention are for the purpose of describing the embodiments and are not intended to limit the present invention.

In this specification, the singular may also include the plural unless specifically stated otherwise in the phrase, and when it is described as “A and (or at least one) of B, C”, it may include one or more of all combinations that may be combined with A, B, C.

In addition, in describing components of the embodiments of the present invention, the terms such as first, second, A, B, (A), (B), etc. may be used. These terms are only intended to distinguish one component from another and are not intended to limit the nature, order, or sequence of the component.

In addition, when a component is described as being ‘connected’, ‘coupled’, or ‘linked’ to another component, it may include not only cases where the component is ‘connected’, ‘coupled’, or ‘linked’ directly to the other component, but also cases in which the component is ‘connected’, ‘coupled’, or ‘linked’ by another component between the component and the other component.

In addition, when described as being formed or arranged “above (upper)” or “below (lower)” each component, “above (upper)” or “below (lower)” includes not only the case where the two components are in direct contact with each other, but also the case in which one or more other components are formed or arranged between the two components. In addition, when expressed as “above (upper)” or “below (lower)”, it may include the meaning of not only the upward direction but also the downward direction based on one component.

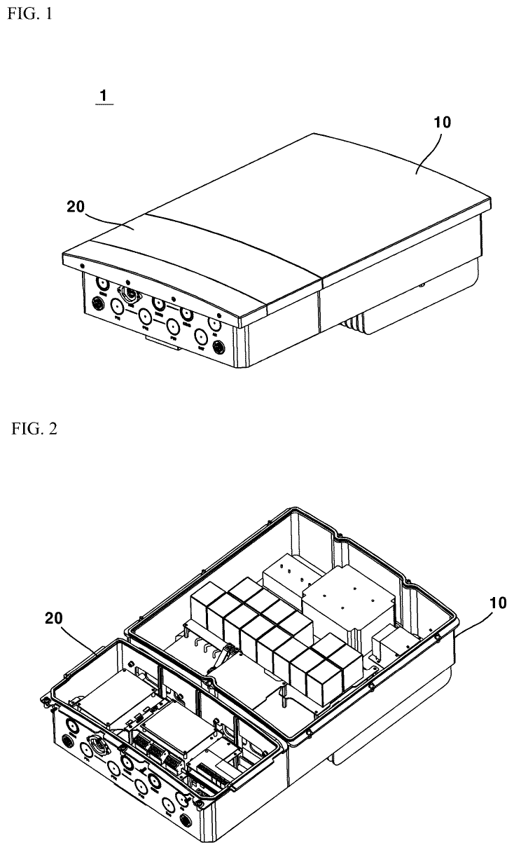

FIG. 1 is a perspective view of an inverter module according to an embodiment of the present invention.

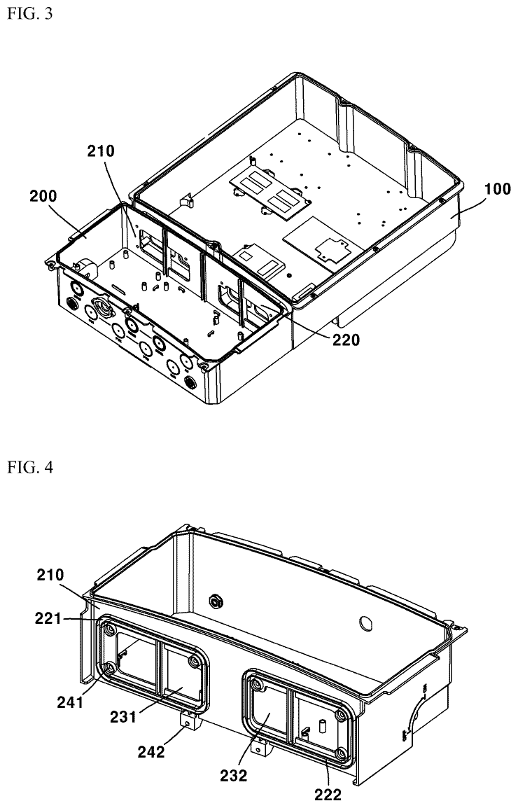

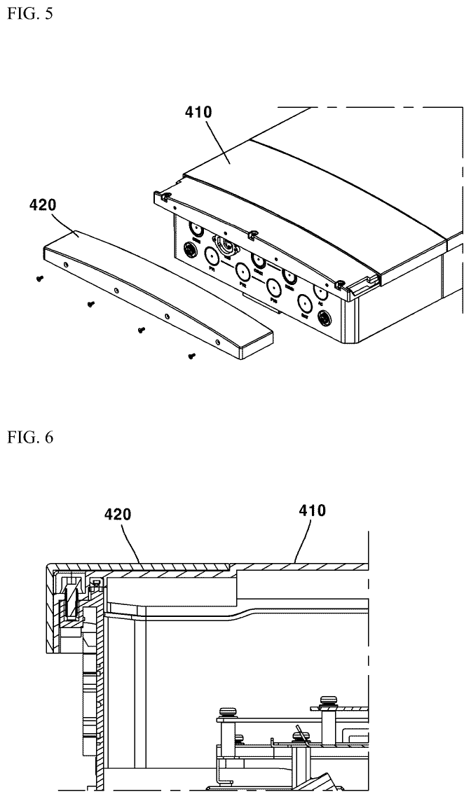

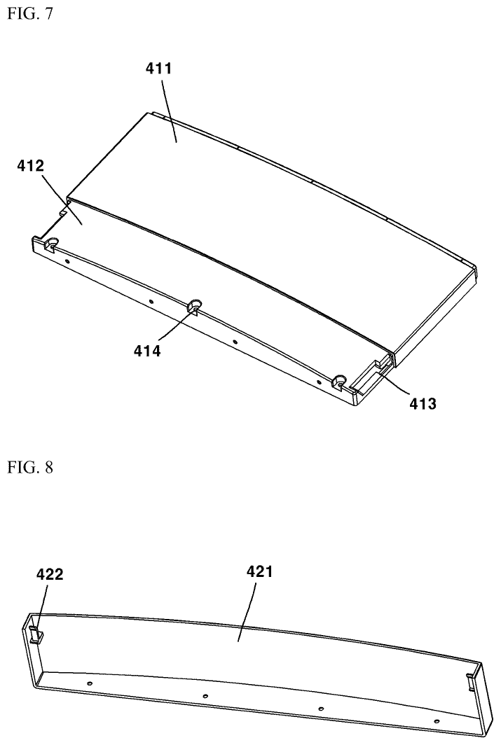

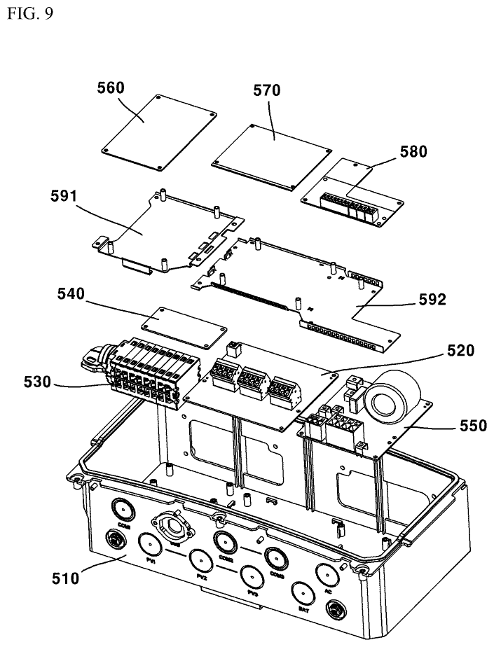

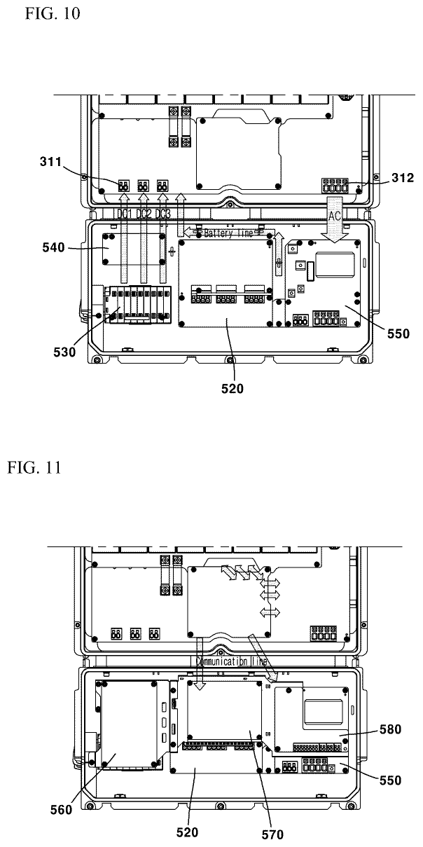

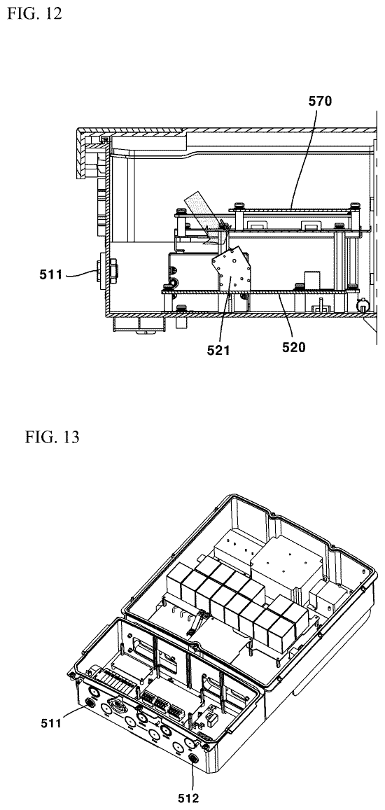

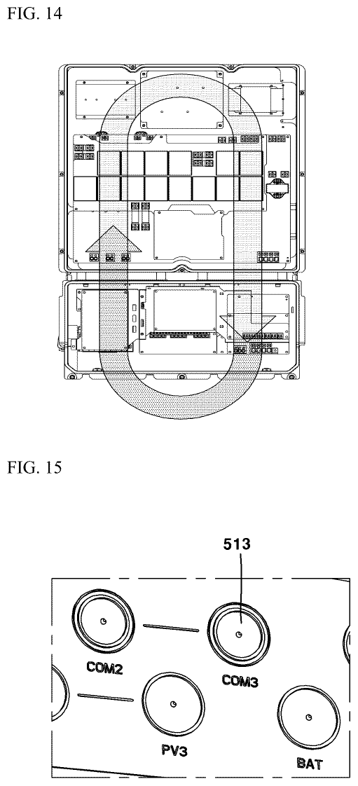

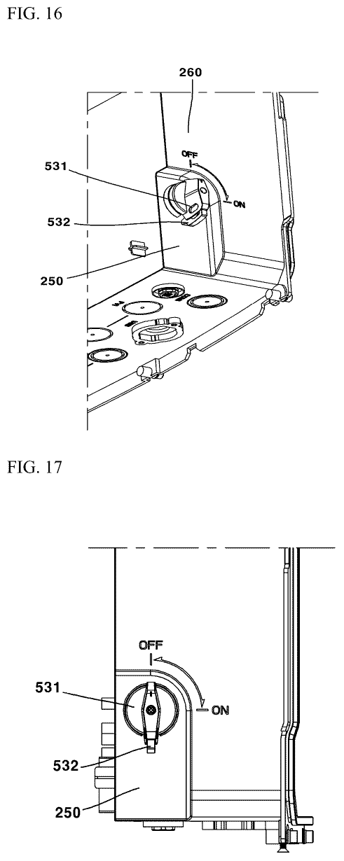

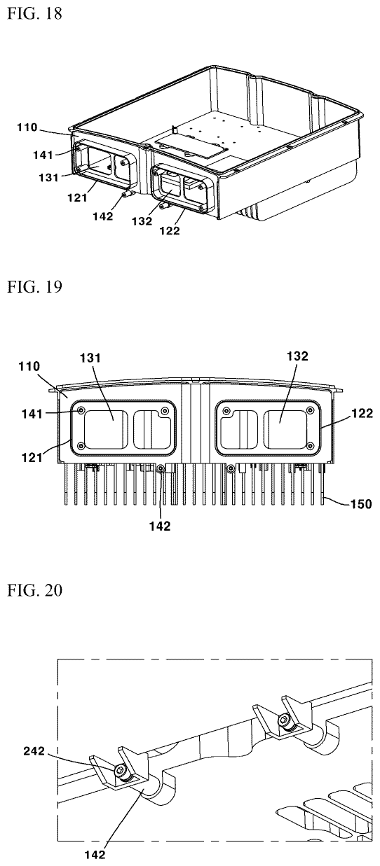

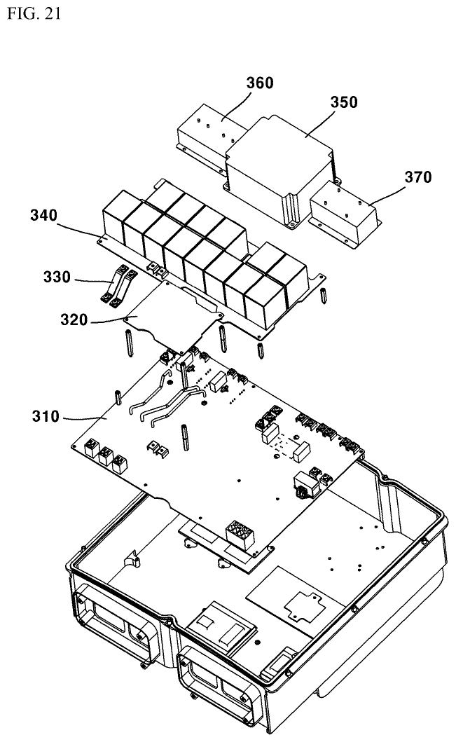

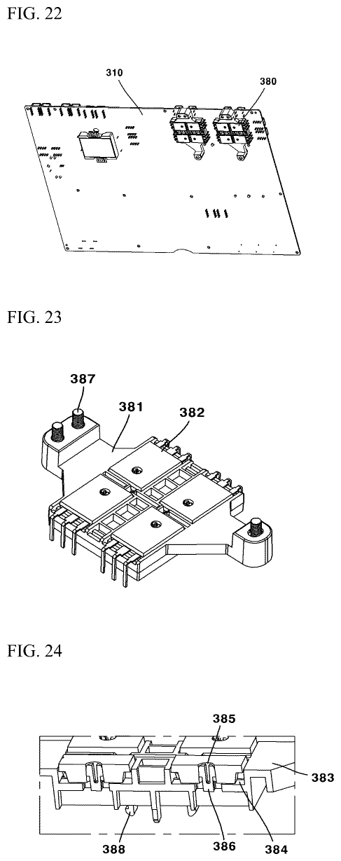

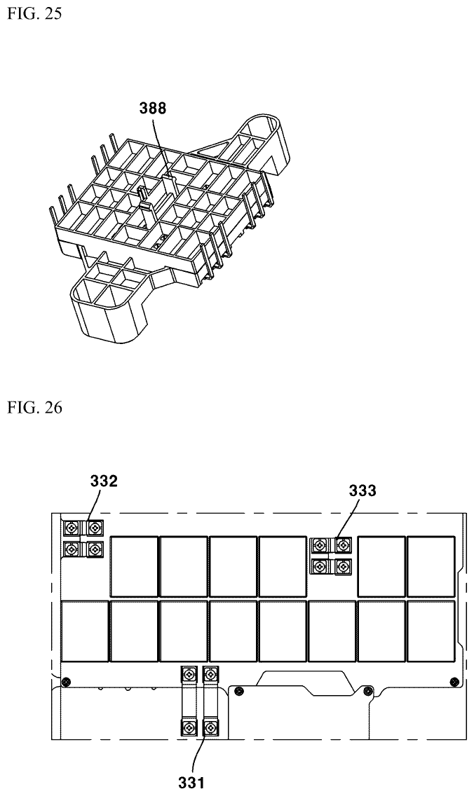

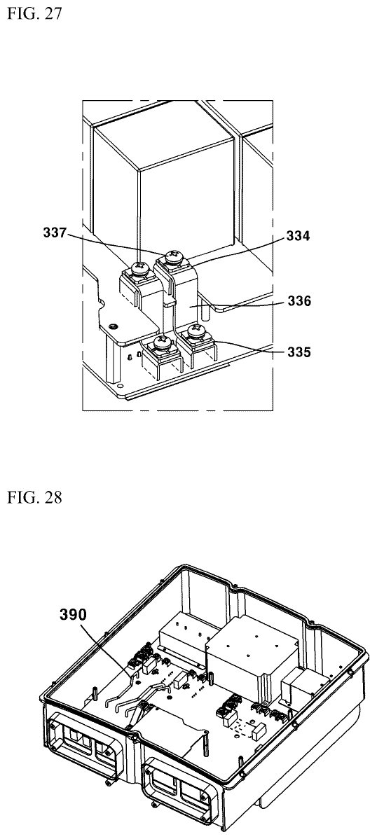

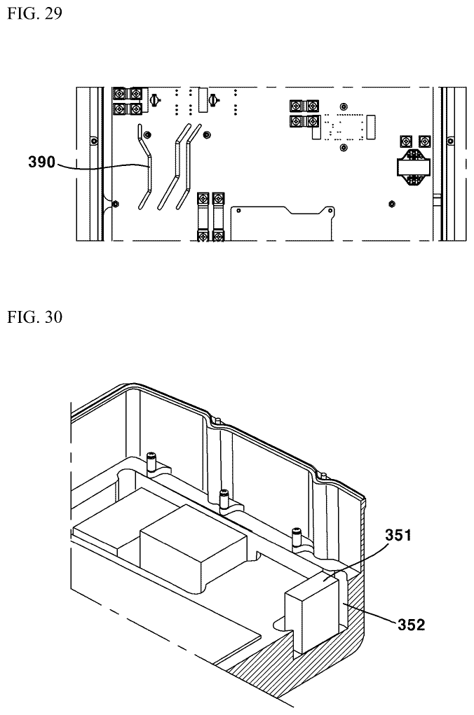

FIG. 2 is a view illustrating the inside of the inverter module according to an embodiment of the present invention, FIG. 3 is a view illustrating an inverter module case according to an embodiment of the present invention, FIG. 4 is a view for explaining a wire connection module case according to an embodiment of the present invention, FIG. 5 is a view for explaining a wire connection module case cover according to an embodiment of the present invention, FIGS. 9 to 12 are views for explaining a configuration of a wire connection unit according to an embodiment of the present invention, FIGS. 13 and 14 are views for explaining an air circulation of an inductor module according to an embodiment of the present invention, FIG. 15 is a view for explaining a hole guide of the inductor module according to an embodiment of the present invention, FIGS. 16 and 17 are views for explaining a switch knob of the inductor module according to an embodiment of the present invention, FIGS. 18 to 20 are views for explaining an inductor module case according to an embodiment of the present invention, FIG. 21 is a view for explaining a configuration of an inductor drive part according to an embodiment of the present invention, FIGS. 22 to 25 are views for explaining a switching element module according to an embodiment of the present invention, FIGS. 26 and 27 are views for explaining a busbar of the inductor module according to an embodiment of the present invention, FIGS. 28 and 29 are views for explaining a circular busbar of the inductor module according to an embodiment of the present invention, and FIG. 30 is a view for explaining a structure of an embedded inductor of the inductor module according to an embodiment of the present invention.

An inverter module 1 according to an embodiment of the present invention is constituted by an inverter driving unit 10 and a wire connection unit 20. The inverter module 1 may be a PV inverter module. The PV inverter module is a device that receives power from a PV panel or a PV converter to convert the power into power that is capable of being used in homes or buildings. Thus, the PV inverter receives DC power from the PV converter to convert the DC power into AC power, thereby outputting the converted AC power. Here, the DC power is transmitted to the inverter driving unit 10 through the wire connection unit 20, the inverter driving unit 10 converts the power to transmit the converted power to a load through the wire connection unit 20. The inverter driving unit 10 may include a power conversion element and a switching element or MCU that controls the power conversion element to convert the power. The inverter driving unit 10 may include an inductor or capacitor as the power conversion element, a switching element implemented as a FET or diode, and an MCU that controls the switching element. In addition, the inverter driving unit 10 may include various elements for converting the power or elements for implementing functions other than the power conversion.

The inverter module 1 according to an embodiment of the present invention is implemented as one module through an inverter module case. The inverter module case is constituted by a case of each of the inverter driving unit 10 and the wire connection unit 20, and the cases may be connected to each other to provide one inverter module case.

The inverter module case is constituted by a first case 100 and a second case 200. The inverter driving unit 10 is disposed inside the first case 100, and the wire connection unit 20 is disposed inside the second case 200. Here, the second case 200 in which the wire connection unit 20 is disposed may be called a wire connection module and also may be called a wiring box or a junction box.

Here, the inverter driving unit 10 may be a drive part of a 7.6 KW inverter or an 11.4 KW inverter module. Here, even if the type of inverter is different, a surface coupled to the wire connection unit 20 may have the same horizontal length to perform wire connection using one wire connection module even though the type of inverter is different. That is, the wire connection module may be applied by standardizing a coupling structure as a detachable modular type. As a result, the standardization structure for each product may be reduced in initial mold investment cost, and various lineups according to the type of inverter may be unified to provide a family look.

The first case 100 and the second case 200 may have two through-holes 210 and 220, through which a wire connecting the inverter driving unit 10 to the wire connection unit 20 passes, in the surfaces, which are coupled to each other. The inverter driving unit 10 and the wire connection unit 20 are connected through the two through-holes 210 and 220. Here, the inverter driving unit 10 and the wire connection unit 20 may be connected through a wire or busbar. Here, sealing has to be performed to prevent external substances such as water or dust from being introduced through the holes. Particularly, for the inverter module 1 installed at the outside, the sealing that isolates the inside from the outside is important.

The first case 100 may include a sealing protrusion, a through-hole, and a coupling groove at one side surface 11 that is coupled to the second case 200.

The one side surface 110 of the first case 100 coupled to the second case 200 may include a first sealing protrusion 121 and a second sealing protrusion 122, which protrude in a direction, in which the one side surface 110 is coupled to the second case 200, and are spaced apart from each other in a first direction, a first through-hole 131 and a second through-hole 132, which are defined inside sealing spaces, in which the first sealing protrusion 121 and the second sealing protrusion 122 are provided, respectively, one or more first coupling grooves 141 defined inside the sealing space defined by the first sealing protrusion 121 or the second sealing protrusion 122, and one or more second coupling grooves 142 defined outside the first sealing protrusion 121 and the second sealing protrusion 122.

The first sealing protrusion 121 and the second sealing protrusion 122 may protrude in the direction in which the first case 100 and the second case 200 are coupled to define the through-holes 131 and 132 and perform the sealing at the same time. The first sealing protrusion 121 and the second sealing protrusion 122 perform the sealing to isolate the through-hole, through which the wire passes, from the outside. Each of the first sealing protrusion 121 and the second sealing protrusion 122 may be in the form of a band protruding at a predetermined thickness, and the sealing space surrounded by a protruding area may be defined therein. The first through-hole 131 and the second through-hole 132 are defined inside each sealing space.

The first through-hole 131 may be defined to correspond to a shape of the first sealing protrusion 121. The first sealing protrusion 121 may protrude in a rectangular shape, but an edge may be rounded to facilitate coupling of a sealing member. The first through-hole 131 may also be defined in the rectangular shape with the rounded edge. Since the position at which the through-hole is defined may be structurally weak, each of the first through-hole 131 and the second through-hole 132 may include a support member that supports the hole. Here, the support member may be used to support the wire passing through the through-hole.

In order to couple the first case 100 to the second case 200, the first case 100 may include a first coupling groove 141 defined inside the sealing space and a second coupling groove 142 defined outside the sealing space. When the coupling groove is defined only inside the sealing space, there is a problem that a coupling process becomes complicated, and the space in which the sealing has to be performed becomes larger to deteriorate a sealing effect.

The coupling groove may be defined outside the sealing space to not only improve the sealing effect, but also facilitate the process. The first coupling groove 141 may be defined inside the sealing space defined by the sealing protrusion, and the second coupling groove 142 may be defined outside the sealing space defined by the sealing protrusion. The first coupling groove 141 and the second coupling groove 142 may be provided in one or more or plurality. The first case 100 and the second case 200 have to be firmly fixed, and for the multiple coupling, the coupling groove may be provided in plurality.

The first coupling groove 141 may be defined in an area between the first sealing protrusion 121 and the first through-hole 131. The first coupling groove 141 may be defined along the edge of the sealing space. In addition, the second coupling groove 142 may be defined outside the sealing space. As illustrated in FIG. 5, the coupling groove may be defined in a direction of each edge on the basis of the sealing space, and the second coupling groove 142 may be defined in a bottom surface of the first case 100, in which a heatsink 150 is provided, to prevent a load from being concentrated only at a central area during the coupling, thereby distributing the concentration of the load and improving the sealing effect. This may minimize exposure of screw coupling that performed to be coupled to a front surface of the case and connect a coupling point of the second coupling groove 142 to the heatsink 150 to prevent excessive concentration of the load on the second case 200. In addition, since a separate reinforcing frame is not applied, the material costs may be reduced, and the manufacturing process may be simplified, and workability may be improved by minimizing the screw coupling that is performed inside the second case 200.

The first coupling groove 141 and the second coupling groove 153 may be defined in a first surface of the first case 100 or may be defined in the form of a coupling protrusion through a protruding shape. For this, a first coupling protrusion that protrudes in a direction coupled to the second case 200 and including the first coupling groove 141 inside the sealing space defined by the first sealing protrusion 121, and a second coupling protrusion that protrudes in a direction coupled to the second case 200 outside the sealing space defined by the first sealing protrusion 121 and including the second coupling groove 153 may be provided. Here, the first coupling protrusion may be inserted into the first coupling hole 241, and the second coupling protrusion may be inserted into the second coupling hole 242. Each of the first coupling protrusion and the second coupling protrusion may be provided in a protruding shape as illustrated in FIGS. 4 and 6, and the protruding shape may be inserted into each of the first coupling hole 241 and the second coupling hole 242 to guide connection between the first case 100 and the second case 200. The coupling groove may not be connected to the internal space and be provided as a closed structure having a predetermined depth to prevent foreign substances from being introduced into the internal space through the coupling groove.

One side surface 210 of the second case 200 coupled to the first case 100 may be configured to have a structure corresponding to the one side 110 of the first case 100. A first sealing groove 221 and a second sealing groove 222, in which the first sealing protrusion 121 and the second sealing protrusion 122 are accommodated, respectively, a third through-hole 231 and a fourth through-hole 232, which are defined inside the sealing spaces defined by the first sealing groove 221 and the second sealing groove 222, respectively, one or more first coupling holes 241 defined inside the sealing space defined by the first sealing groove 221 or the second sealing groove 222, and one or more second coupling holes 242 defined outside the sealing space in which the first sealing groove 221 and the second sealing groove 222 are defined may be provided. The first coupling groove 141 and the corresponding first coupling hole 241 or the second coupling groove 142 and the corresponding second coupling hole 242 may be screw-coupled.

The first sealing groove 221 and the second sealing groove 222 define grooves into which the sealing protrusions are inserted to correspond to the first sealing protrusion 121 and the second sealing protrusion 122. An uneven shape may be provided to correspond to the shape of the sealing protrusion. The sealing member may be disposed between the sealing groove and the sealing protrusion. That is, the sealing member may be disposed between the sealing groove and the sealing protrusion, and the sealing protrusion may be fitted into the sealing groove to perform the sealing.

The first coupling groove 141 and the first coupling hole 241 may be defined at positions corresponding to each other, and a screw may be inserted from the first coupling hole 241 toward the first coupling groove 141 to perform screw coupling. The second coupling groove 142 and the second coupling hole 242 may also be defined at positions corresponding to each other, and a screw may be inserted from the second coupling hole 242 toward the second coupling groove 142 to perform screw coupling.

The first through-hole 131 and the third through-hole 231 and the second through-hole 132 and the fourth through-hole 232 may define passages passing through the inside of the first case 100 and the inside of the second case 200, respectively. The first through-hole 131 of the first case 100 and the third through-hole 231 of the second case 200 may face each other, but be spaced apart from each other to form a passage. The passage may be defined to pass through which the wire passes, and a space may be defined inside the passage so that ferrite is mounted at the corresponding position for the wire.

A first cover 410 covering the second case 200 may be provided, and the first cover 410 and the second case 200 may be screw-coupled in a vertical direction. Here, in order to prevent the screw coupling 414 from being exposed to a top surface of the first cover 410, a second cover 420 covering an area of the first cover 410 to which the screw coupling may be provided. Here, in order to couple the first cover 410 to the second cover 420, the first cover 410 may include a hook coupling groove in each of both surface thereof, and the second cover 420 may include a third hook part 422 corresponding to the hook coupling groove 413 inside each of both the surfaces.

To prevent a stepped portion from occurring when the first cover 410 and the second cover 420 are coupled to each other, the stepped portion 412 may be provided on the first cover 410. The hook coupling groove 413 may be defined at each of both sides of the corresponding position so that the second cover 420 is fitted and hook-coupled in a direction of the stepped portion 412. The second cover 420 may be provided in a form that covers the stepped portion 412 of the first cover 410, and the third hook part 422 corresponding to the hook coupling groove 413 may be provided at each of both the sides. The screw coupling 414 of the first cover 410 may be prevented from being exposed in an upper direction of the first cover 410 through the hook coupling of the first cover 410 and the second cover 420. The screw coupling may be performed in a lateral direction rather than the upward direction of the first cover 410 together with the hook coupling of the first cover 410 and the second cover 420 to more firmly fix the first cover 410 and the second cover 420.

The wire connection unit 20 may include a plurality of stacked substrates. Here, the wire connection unit 20 may be provided in a structure in which upper and lower layers are stacked. In order to reduce a size of the inverter module 1, the wire connection unit 20 may be disposed in the form of stacking the plurality of substrates to improve efficiency of space utilization. Since the wire connection unit 20 is disposed so that the wire is connected between the substrates, more efficient space arrangement is required. In order to place the plurality of substrates inside the narrow second case, the substrates are disposed separately in the upper and lower layers. For example, the wire connection unit 20 may include six substrates, and thus, the first to third substrates may be disposed on the lower layer, and the fourth to sixth substrates may be disposed on the upper layer.

The lower layer may include a first substrate 520 disposed at a center and having one side connected to an external power input line, a switching part 530 disposed at a side in the first direction, a second substrate 540 disposed at a side in the first direction and having one side connected to an output part of the switching part and the other side connected to a power input part of the inverter driving unit through one through-hole of the two through-holes, and a third substrate 550 disposed at a side in a second direction and having one side connected to the power output part of the inverter driving unit through the other through-hole of the two through-holes and the other side connected to the external power output line. The upper layer may include a fourth substrate 560 disposed at a side in the first direction and having one side connected to the first substrate 520 and the other side connected to the switching part 530, a fifth substrate 570 disposed at a center and connected to a communication part of the inverter driving unit 10, and a sixth substrate 580 disposed at a side in the second direction and connected to the communication part of the inverter driving unit 10.

The inverter module 1 receives DC power from the outside, i.e., from the PV panel to convert the DC power into AC power, thereby transmitting the converted AC power to the grid or load. Alternatively, the inverter modulel may output power to a battery to charge the battery, or receive power from the battery to convert the power to AC power.

In order to improve efficiency of the connection relationship, the substrates connected to power system lines that input or output power may be preferentially disposed on the lower layer, and the substrates that are not disposed on the lower layer and the substrates connected to communication system lines may be disposed on the upper layer.

The first to fourth substrates 520, 540 to 560 may be connected to the power system lines, and the fifth substrate 570 and sixth substrate 580 may be connected to the

### Communication System Lines.

Each of the first to sixth substrates may be a substrate including a programmable logic controller (PLC) part, an arc fault circuit interrupter (AFCI) part, an AC power output part, an electromagnetic interference (EMI) filter part, an energy management system (EMS) part, and a communication part. When the DC power is input from the outside and transmitted to the inverter driving unit 10, the DC power may pass through the PLC part, the EMI filter part, the switching part, and the AFCI part. The PLC part monitors and transmits input power according to preset conditions. Here, the EMI filter part may block EMI introduced from the outside to protect the inverter driving unit 10. The wire passing through the EMI filter part may be input to the switching part 530, and then, whether or not input to the inverter driving part 10 may be controlled. If abnormality occurs, the switching part 530 may block the input to the inverter driving unit 10 to protect the inverter driving unit 10. The power output from the switching part 530 is input to the inverter driving unit 10 as stable and safe power in the state in which arc is blocked in the final AFCI part. When the inverter module is connected to the battery, a battery power line may be connected to the inverter driving unit 10 through a separate connection line.

Here, power transmitted from an external power input line to the PLC part of the first substrate 520, the EMI filter part of the fourth substrate 560, the switching part 530, and the AFCI part of the second substrate 540 is direct current (DC) power. The direct current power input to the inverter driving unit 10 is converted into alternating current (AC) power and then output to an AC power output part of the third substrate 550. The AC power output part is connected to an external power output line to output the AC power to the grid or load.

The EMS part of the fifth substrate 570 and the communication part of the sixth substrate 580 may receive information from the inverter driving unit 10 or transmit a control signal received from an external MCU, etc., to the inverter driving unit 10.

The wire connection unit 20 may include respective shield frames 591 and 592 to protect the fourth substrate 560 on which the EMI filter part is disposed and the fifth substrate 570 on which the EMS part is disposed.

As described above, the external power input line has to be connected to the first substrate 520, and the fifth substrate 570 may be disposed on an upper portion of the first substrate 520 so that the first substrate overlaps at least partly the fifth substrate in the direction of stacking. Thus, the connection between the external power input line and the first substrate 520 may be interrupted by the fifth substrate 570. To solve this problem, the first substrate 520 may include a connector 521 connected to the external power input line. The connector 521 may be disposed on a first area of the first substrate 520 that includes at least a portion of an area overlapping the fifth substrate 570 in the direction of stacking, and a coupling surface coupled to the external power input line may be provided to protrude obliquely so as to face an internal space region in which the fifth substrate 570 is not disposed. When the connector 521 is disposed on an area that does not overlap the fifth substrate 570, the connector 521 may be disposed too close to a side surface into which the external power input line is inserted, so that a space in which the external power input line is bent toward the first substrate 520 may not be secured, and thus, it is difficult to be connected to the first substrate 520. Since many elements are disposed on the first substrate 520, and thus, there is not much free space, it may be difficult to freely design the connector 521. In an environment in which a portion of the area, on which the connector 521 is disposed on the first substrate 520, overlaps the fifth substrate 570 in the direction of stacking, the connector 521 may protrude to protrude diagonally rather than vertically. As illustrated in FIG. 12, the connector 521 may be provided to protrude obliquely so that the coupling surface coupled to the external power input line faces the internal space region in which the fifth substrate 570 is not disposed, thereby connecting the external power input line to the first substrate 520. This enables connection to the external power input line even in the environments in which the substrates are stacked on the upper portion to allow for efficient use of the space.

The second case 200 may include two air inlet-outlets 511 and 512 facing the two through-holes 210 and 220 at the side surface 510 opposite to the one side surface in which the two through-holes 210 and 220 are defined. One of the two air inlet-outlets may allow air to be introduced from the outside, and the other may allow air to be discharged to the outside. Here, a height of each of the air inlet-outlets 511 and 512 may correspond to a height of a space between the substrate disposed on the lower layer and the substrate disposed on the upper layer. This will minimize an interference with the airflow, such as being blocked or split by the substrate. The two air inlet-outlets 511 and 512 may be provided, and thus, as illustrated in FIG. 14, a path through which air is circulated may be provided to improve efficiency of heat dissipation.

A plurality of coupling hole forming guides 513 capable of defining coupling holes having multiple diameters at the side surface 510 opposite to the one side surface in which the two through-holes 210 and 220 are defined may be provided, and the coupling holes may be defined to be through-coupled when connected to the external input/output line. The power input lines, the power output lines, the communication lines, etc., which are connected to the outside, may be inserted into the inside of the second case 200 and then connected. Here, the power input lines, the power output lines, the communication lines may be inserted into the inside of the second case 200 through the coupling holes. Conduit hole specifications of an external connection wire may be different, and to improve compatibility, the coupling hole forming guide having the multiple diameters may be included so that the coupling holes have the multiple diameters. For example, a guide having a diameter of ¾″ or 1″ may be provided, and thus, a worker may form the coupling hole on the basis of the diameters of the external connection wire.

The second case 200 may include a stepped portion 250 on which a switch knob 531 of the switching part 530 is disposed on an outer surface of the side surface in the first direction, and the switch knob 531 may include a locking bar 532 that is inserted and fixed into the inside of the switch knob when the switch knob is in an off position, and thus, the stepped portion 250 may be provided to be opened in a direction in which the locking bar 532 is directed when the switch knob 531 rotates. Here, the locking bar may be disposed to protrude downward from the second case 200 more than a bottom surface of the second case 200 when the switch knob 531 is in an on position.

The switching part 530 disposed inside the second case 200 may be provided so that the switch knob is exposed to the side surface of the second case to operate manually. Here, in order to prevent the switch knob from protruding excessively to the side surface, the stepped portion 250 may be disposed on the side surface on which the switch knob 531 is disposed. The stepped portion 250 may be provided so that the outermost end that is directed outward from the side surface of the switch knob 531 does not protrude more than the outermost end of the inverter module 1 directed in the same direction. Here, the switch knob 531 has to rotate to turn on and off, and the stepped portion 250 may be provided to be opened so that there are no obstacles in the direction in which the locking bar 532 is directed when the switch knob 531 rotates. This allows the user to easily manipulate the switch knob 531 without the interference of the second case 200.

The switch knob 531 may include the locking bar 532 as a knob including a locking function. When the switch knob 531 is in the off position, a catch may be fitted in a state in which the locking bar is inserted into the switch knob 531 to prevent the switch knob 531 from rotating to the on position.

The locking bar 532 may be disposed to protrude outward when the switch knob 531 is turned on. The switch knob may be disposed so that the corresponding position is disposed to protrude downward from the second case 200 more than the bottom surface of the second case 200, and thus, the worker allows the switch knob to be easily held so as to rotate to be turned off.

The inverter driving unit 10 may be disposed inside the first case 100 and may include one or more substrates and a plurality of elements for power conversion. For example, as illustrated in FIG. 7, the inverter driving unit 10 may include a main board 310, an auxiliary board 320, a busbar 330, a DC link capacitor board 340, an inverter side inductor 350, a DC-DC inductor 360, and a grid side inductor 370.

Elements that are necessary for converting power may be disposed on the main board 310. In order to perform the power conversion, a plurality of switching elements may be provided, and power may be converted by controlling an operation of each of the switching elements. Here, the plurality of switching elements may be mounted on the main board 310 through a switching element module.

The switching element module 380 may include one or more switching elements 382 and a switching element holder 381 that accommodates the switching elements 382, and the switching element holder 381 may include a base 381, a switching element accommodation part 384, in which the one or more switching elements 382 are accommodated in one surface of the base 383, a first hook part 386 that is disposed in the switching element accommodation part 384 and is hook-coupled to a coupling hole 385 of the switching element 382, a coupling protrusion 387 that extends from one surface of the base 383 and is coupled to a bottom surface of the first case, and a second hook part 388 that extends from the other surface of the base 383 and is coupled to the main board.

Since a large amount of heat is generated in the switching element, the switching element holder 381 that applies a pressure of the heat dissipation part of the element to maintain contact with the heat dissipation part such as the heatsink. The switching element 382 may be coupled to the switching element holder 381 to provide a switching element module. The switching element module may be assembled at the outside and mounted on the inverter module. The switching element module may be various elements that generate heat and an element holder that accommodate the corresponding elements in addition to the switching element. The switching elements may be elements including a body and an extension pin extending from the body and connected to the board.

As illustrated in FIG. 9, the switching element module 380 may include a switching element holder 381 that accommodates the switching elements and one or more switching elements 382 disposed in the switching element holder 381. Here, the switching element may be a semiconductor element such as a FET or a diode.

Here, the switching element 382 includes a body and one or more connection pins extending from the body, and the switching element holder 381 includes a base 383 and a switching element accommodation part 384 which is provided in the base 383 and in which one or more switching elements are accommodated. The body of the switching element that generates heat has to be in contact with the heatsink, and the connection pins have to be connected to the board. The connection pin may extend to be connected toward the main board 310 by bypassing the outside of the switching element accommodation part 384.

The switching element holder 381 extends from the first surface of the base 383 and includes a first hook part 386 that is hook-coupled to the coupling hole 385 of the switching element 382. The switching element 382 is fixed to the switching element holder 381 through the hook coupling of the first hook part 386.

As illustrated in FIG. 9, four switching elements may be disposed in the switching element holder 381. Here, a height tolerance between components may occur when assembled with the board. To compensate for the height tolerance, a thermal pad may be applied to ensure stable heat dissipation performance. The thermal pad may be adjusted in thickness when pressed to compensate for the height tolerance. Here, a size of the thermal pad has to be sufficiently wide to secure an insulating distance between the switching element and the heatsink. For example, the thermal pad may be formed to be longer than 15 mm on all four surfaces of each of the switching elements.

The thermal pad may include a coupling protrusion 387 extending from one surface of the base 383 and coupled to a bottom surface of the first case. A heatsink, which is a heat dissipation part, may be disposed at a lower portion of the switching element holder 620. In order to improve a heat transfer rate to the heatsink, a thermal pad may be provided. The heatsink may prevent electrical connection between the switching element and the heatsink when the switching element and the heatsink are in direct contact with each other. The switching element holder 381 may be fixed to be in contact with the lower portion of the first case 100, i.e., the heatsink through the connecting protrusion 387. A coupling hole may be defined in the coupling protrusion 387 so that the switching element holder 381, the thermal pad, and the lower portion of the second case are screw-coupled in one body. In addition, other components may be pressed to be integrated. A screw may be inserted into the coupling hole of the switching element holder 381, so that the board, the switching element holder 381, and the thermal pad, and the heatsink are connected to be integrated with each other, thereby pressing the switching element 382 toward the heatsink.

The switching element holder 381 may be fixed to the main board 310 through the hook coupling with the board of the second hook part 388. The second hook part 388 may include a second hook part 388 that extends from the other surface of the base 383 and is coupled with the main board 310. The second hook part 388 may be inserted into a hole defined in the main board 310 and coupled to the main board 310.

As illustrated in FIG. 9, four switching elements may be coupled to the board and the heatsink at once to secure the heat dissipation performance through a structure of the switching element holder having the above-described structure.

The first case 100 may include a recessed portion of which a bottom surface corresponding to the position of the switching element module is recessed inward, and a heat dissipation fin may be disposed on an outer surface of the recessed portion. In order to release the heat generated in the switching element 382 to the outside, the first case 100 may include a recessed portion that is recessed inward toward the switching element 382 so as to be in contact with the heatsink of the second case. As a result, the heat emitted from the switching element 382 may be efficiently released.

The inverter driving unit 10 may include a plurality of substrates that are stacked and spaced apart from each other and a busbar that electrically connects the plurality of substrates to each other. The busbar may include an upper substrate coupling part coupled to an upper substrate, a lower substrate coupling part coupled to a lower substrate, and a connection support that extends from the upper substrate coupling part and the lower substrate coupling part in a direction in which the upper substrate and the lower substrate are spaced apart from each other to support the upper substrate.

In order to reduce the module size, a plurality of substrates may be disposed inside the first case 100 in a stacked form and spaced vertically apart from each other. Here, in order to electrically connect the main board 310 which is the lower substrate and the DC link capacitor substrate 340 which is the upper substrate, one or more busbars may be provided. Each of the busbars may have a structure which is simply electrically connected and also connects the upper substrate coupling part 334 coupled to the upper substrate to the lower substrate coupling part 335 coupled to the lower substrate and vertically supports the upper substrate and the lower substrate. Due to the narrow space, heavy elements such as capacitors may be disposed on the upper substrate. Here, the upper substrate may be firmly supported by providing a structure so that the busbar acts as a support. In addition, the screw hole of the substrate stacked on the upper portion may be deleted, the substrate mounting space may be secured, and the number of screw couplings may be reduced to reduce material costs.

Here, the busbar may be disposed on an edge of each of the upper substrates 331 and 332 or disposed in a hole defined in a central area of the upper substrate 333. A support may be disposed not only at the edge but also at the central area to more firmly support the upper substrate. The first busbar 331 may connect an input and output of battery power to the battery power busbar. Here, the support of the first busbar 331 may extend diagonally rather than vertically. This may vary depending on a layout design of the substrate and a terminal. The second busbar 332 may be connected to the input of the DC power through the DC switching element disposed at a lower portion of the main board, and the third busbar 333 may output power to an IGBT, which is a switching element disposed at the lower portion of the main board.

In case of an insufficient PCB pattern space, the space may be utilized by connecting a separate circular busbar line in the air, as illustrated in FIGS. 14 and 15.

The inverter driving unit may include one or more inductors 350 disposed on one side surface of the first case 100, which is opposite to the other side coupled to the second case 200. The large inductors 350, 360, and 370 may be disposed at an end of the first case 100 to increase in space utilization, and the inductors 350, 360, and 370 that generate a large amount of heat may be disposed in a space disposed at the uppermost end when installing the product to efficiently perform heat conduction and natural heat dissipation. In order to optimize the connection between each of the inductors 350, 360, and 370 and the main board 310, connection terminals of the main board 310 and the inductors 350, 360, and 370 may be disposed close to the inductors 350, 360, and 370.

The first case 100 may include an accommodation groove 352 that accommodates an inductor 351. The inductor 351 may be disposed inside the accommodation groove 352, and the heat dissipation fin may be disposed outside an area, on which the inductor 351 is disposed, to efficiently release the heat generated from the inductor 351. In addition, the inductor 351 may be disposed inside the accommodation groove 352 and then embedded and fixed through molding, and thus, the inductor may be fixed without a separate fixing member, and also, the heat dissipation may be efficiently performed. As a height of the inductor is reduced, the DC link capacitors may be disposed to overlap an upper portion of the inductor. This allows for more efficient use of the space. The accommodation groove accommodating the inductor may be applied to a 11.4 KW inverter module. A 7.6 KW inverter module may not have the accommodation groove that accommodates the inductor.

The inverter driving unit 10 may include an auxiliary substrate 320 on which an auxiliary power part is disposed, and the auxiliary substrate 320 may be disposed on one side surface that is coupled to the second case 200. An auxiliary power (AUX POWER) part may be disposed on the auxiliary substrate 320 and may be disposed on the upper portion of the main board 310 and also may be disposed close to the second case 200 for the connection to the wire connection unit 20. Here, the auxiliary substrate 320 may be connected to the main board 310 through a wire. This may be applied to both 7.6 KW and 11.4 KW inverter modules.

Although the present invention has been described with specific details such as specific components and limited examples and drawings, these have been provided only to assist a more general understanding of the present invention, and the present invention is not limited to the above-described examples, and those skilled in the art to which the present invention pertains can make various modifications and variations from this description.

Therefore, the idea of the present invention should not be limited to the described embodiments, and all things that are equivalent or equivalent to the claims described below as well as the claims are included in the scope of the idea of the present invention.

1.-10. (canceled)

11. A wire connection module connecting an inverter driving unit of an inverter module to external input/output lines, the wire connection module comprises:
a wire connection unit connecting the inverter driving unit to the external input/output lines; and
a case in which the wire connection unit is disposed,
wherein the wire connection unit comprises a plurality of substrates that are stacked, and
wherein the case comprises two through-holes, through which a wire passes, in one side surface thereof.

12. The wire connection module according to claim 11, wherein the wire connection unit is formed by a structure in which an upper layer and a lower layer are stacked,
wherein the lower layer comprises:
a first substrate disposed at a center and having one side connected to an external power input line;
a switching part disposed at a side in a first direction;
a second substrate disposed at a side in the first direction and having one side connected to an output part of the switching part and the other side connected to the power input part of the inverter driving unit through one through-hole of the two through-holes; and
a third substrate disposed at a side in a second direction and having one side connected to a power output part of the inverter driving unit through the other through-hole of the two through-holes and the other side connected to the external power output line.

13. The wire connection module according to claim 12, wherein DC power is input/output into/from the first substrate and the second substrate, and
wherein AC power is input/output into/from the third substrate.

14. The wire connection module according to claim 12, wherein the upper layer comprises:
a fourth substrate disposed at a side in the first direction and having one side connected to the first substrate and the other side connected to the switching part;
a fifth substrate disposed at a center and connected to a communication part of the inverter driving unit; and
a sixth substrate disposed at a side in the second direction and connected to the communication part of the inverter driving unit.

15. The wire connection module according to claim 14, wherein the first substrate at least partially overlaps in a direction of stacking, and
wherein the first substrate comprises a connector connected to the external power input line,
wherein the connector is disposed on a first area of the first substrate comprising at least a portion of an area that overlaps the first substrate in the direction of stacking, and
wherein a coupling surface coupled to the external power input line protrudes to be inclined toward an internal space region in which the fifth substrate is not disposed.

16. The wire connection module according to claim 14, wherein the first to fourth substrates are connected to a power system line, and
the fifth and sixth substrates are connected to a communication system line.

17. The wire connection module according to claim 14, wherein each of the first to sixth substrates comprises a programmable logic controller (PLC) part, an arc fault circuit interrupter (AFCI) part, an AC power output part, an electromagnetic interference (EMI) filter part, an energy management system (EMS) part, and a communication part.

18. The wire connection module according to claim 11, wherein the case comprises two air inlet-outlets, which respectively face the two through-holes, disposed at a side surface facing the one side surface in which the two through-holes are formed.

19. The wire connection module according to claim 18, wherein one of the two air inlet-outlets is configured to allow air to be introduced from outside, and the other is configured to allow air to be discharged to outside.

20. The wire connection module according to claim 11, wherein the case comprises a plurality of coupling hole forming guides, which are configured to form coupling holes having multiple diameters, on a side surface facing the one side surface in which the two through-holes are formed, and
wherein the coupling holes are formed to be through-coupled when connected to the external input/output lines.

21. The wire connection module according to claim 12, wherein the case comprises a stepped portion on which a switch knob of the switching part is disposed on an outer surface of a side surface in the first direction,
wherein the switch knob comprises a locking bar inserted and fixed into inside of the switch knob when the switch knob is in off-position, and
wherein the stepped portion is formed to be opened in a direction in which the locking bar is directed when the switch knob rotates.

22. The wire connection module according to claim 21, wherein the locking bar is disposed to protrude downward from the case more than a bottom surface of the case when the switch knob is in on-position.

23. An inverter module, comprising:
an inverter driving unit configured to convert power; and
a wire connection unit connecting the inverter driving unit to external input/output lines,
wherein the wire connection unit comprises:
a wire connection unit connecting the inverter driving unit to the external input/output lines; and
a case in which the wire connection unit is disposed,
wherein the wire connection unit comprises a plurality of substrates that are stacked, and
wherein the case comprises two through-holes, through which a wire passes, in one side surface thereof.

24. The inverter module according to claim 23, wherein the wire connection unit is formed by a structure in which an upper layer and a lower layer are stacked,
wherein the lower layer comprises:
a first substrate disposed at a center and having one side connected to an external power input line;
a switching part disposed at a side in a first direction;
a second substrate disposed at a side in the first direction and having one side connected to an output part of the switching part and the other side connected to the power input part of the inverter driving unit through one through-hole of the two through-holes; and
a third substrate disposed at a side in a second direction and having one side connected to a power output part of the inverter driving unit through the other through-hole of the two through-holes and the other side connected to the external power output line.

25. The inverter module according to claim 24, wherein DC power is input/output into/from the first substrate and the second substrate, and
wherein AC power is input/output into/from the third substrate.

26. The inverter module according to claim 24, wherein the upper layer comprises:
a fourth substrate disposed at a side in the first direction and having one side connected to the first substrate and the other side connected to the switching part;
a fifth substrate disposed at a center and connected to a communication part of the inverter driving unit; and
a sixth substrate disposed at a side in the second direction and connected to the communication part of the inverter driving unit.

27. The inverter module according to claim 26, wherein the first substrate at least partially overlaps in a direction of stacking,
wherein the first substrate comprises a connector connected to the external power input line,
wherein the connector is disposed on a first area of the first substrate comprising at least a portion of an area that overlaps the first substrate in the direction of stacking, and
wherein a coupling surface coupled to the external power input line protrudes to be inclined toward an internal space region in which the fifth substrate is not disposed.

28. The inverter module according to claim 26, wherein the first to fourth substrates are connected to a power system line, and
the fifth and sixth substrates are connected to a communication system line.

29. The inverter module according to claim 26, wherein each of the first to sixth substrates comprises a programmable logic controller (PLC) part, an arc fault circuit interrupter (AFCI) part, an AC power output part, an electromagnetic interference (EMI) filter part, an energy management system (EMS) part, and a communication part.

30. The inverter module according to claim 23, wherein the case comprises two air inlet-outlets, which respectively face the two through-holes, disposed at a side surface facing the one side surface in which the two through-holes are formed.
